(19) United States
(12) Patent Application Publication
(10) Pub. No.: US 2026/0271461 A1
(43) Pub. Date: Sep. 10, 2026

(54) LIGHT-EMITTING DEVICE, MANUFACTURING METHOD THEREFOR, DISPLAY PANEL, AND DISPLAY DEVICE

(71) Applicants: Beijing BOE Technology Development Co., Ltd., Beijing (CN); BOE Technology Group Co., Ltd., Beijing (CN)

(72) Inventors: Qian SUN, Beijing (CN); Mingxing WANG, Beijing (CN); Wei LI, Beijing (CN); Huajie YAN, Beijing (CN); Zhiqiang JIAO, Beijing (CN); Qian JIN, Beijing (CN)

(21) Appl. No.: 18/842,378

(22) PCT Filed: Nov. 7, 2023
(86) PCT No.: PCT/CN2023/130219

§ 371 Date: Aug. 28, 2024

(51) Int. Cl. H10H 29/851; H10H 20/812; H10H 20/823; H10H 20/825

(52) U.S. Cl. CPC H10H 29/8514; H10H 20/812; H10H 20/823; H10H 20/825

(57) ABSTRACT

Embodiments of the present disclosure provide a light-emitting device, a manufacturing method therefor, a display panel, and a display device, belonging to the field of display technology. The light-emitting device includes a light-emitting layer and a color conversion layer, and the light-emitting layer includes at least one light-emitting unit, and the color conversion layer is disposed on a first surface of the light-emitting layer. The color conversion layer includes multi-quantum wells and is made of inorganic material.

### CROSS-REFERENCE TO RELATED APPLICATION

This application is a US national stage of international application No. PCT/CN2023/130219, filed on Nov. 7, 2023, the disclosure of which is incorporated herein by reference in its entirety.

### TECHNICAL FIELD

The embodiments of the present disclosure relate to the field of display technologies, and in particular, to a light-emitting device, a manufacturing method therefor, a display panel, and a display device.

### BACKGROUND

Display devices have been used in a variety of scenarios in life, such as cell phones, tablet computers, and other electronic devices. The light-emitting device is an important part of the display device.

In the related art, the light-emitting device includes a light-emitting layer and a color conversion layer, where the light-emitting layer includes at least one light-emitting unit, the color conversion layer is disposed on a side of the light-emitting layer, the color conversion layer includes at least one quantum dot color conversion unit in one-to-one correspondence to the at least one light-emitting unit, and the quantum dot color conversion unit is made of organic material.

However, because the quantum dot color conversion unit is made of organic material, the color conversion layer has problems of poor temperature resistance and poor reliability.

### SUMMARY

Embodiments of the present disclosure provide a light-emitting device, a manufacturing method therefor, a display panel, and a display device, which can improve the problem of poor temperature resistance and poor reliability of the color conversion layer made of organic material. The technical solutions are as follows.

According to an aspect, a light-emitting device is provided. The light-emitting device includes a light-emitting layer and a color conversion layer, the light-emitting layer including at least one light-emitting unit, and the color conversion layer is disposed on a first surface of the light-emitting layer; where the color conversion layer includes multi-quantum wells and is made of inorganic material.

Optionally, the at least one light-emitting unit includes a first light-emitting unit, a second light-emitting unit, and a third light-emitting unit, and the color conversion layer includes a first color conversion layer and a second color conversion layer stacked sequentially in a direction from close to the light-emitting layer to away from the light-emitting layer ; where an orthographic projection of the first color conversion layer on the first surface is at least partially overlapped with an orthographic projection of the first light-emitting unit on the first surface, and the first color conversion layer is configured to convert light emitted by the first light-emitting unit to light of a first color; and an orthographic projection of the second color conversion layer on the first surface is at least partially overlapped with an orthographic projection of the second light-emitting unit on the first surface, and the second color conversion layer is configured to convert light emitted by the second light-emitting unit to light of a second color.

Optionally, the light-emitting device further includes a first adhesion layer and a second adhesion layer, the first adhesion layer is disposed between the light-emitting layer and the color conversion layer, the second adhesion layer is disposed between the first color conversion layer and the second color conversion layer, and the first adhesion layer and the second adhesion layer are both made of transparent material.

Optionally, each of the at least one light-emitting unit is configured for emitting blue light.

Optionally, the color conversion layer further includes a third color conversion layer, and the third color conversion layer is disposed on a side, away from the second color conversion layer, of the first color conversion layer; and the third color conversion layer is configured to convert light emitted by the third light-emitting unit to light of a third color, and an orthographic projection of the third color conversion layer on the first surface is at least partially overlapped with an orthographic projection of the third light-emitting unit on the first surface.

Optionally, each of the at least one light-emitting unit is configured to emit ultraviolet light.

Optionally, each of the at least one light-emitting unit includes a first pin and a second pin, and the first pin and the second pin are disposed on a side, away from the color conversion layer, of the light-emitting unit.

Optionally, a first light-emitting unit, a second light-emitting unit and a third light-emitting unit, which are adjacent, form an integrative structure and share one first pin.

Optionally, the first color conversion layer includes laminated M first repeating units, and each of the M first repeating units includes a first barrier layer and a first well layer stacked in a direction from close to the first surface to away from the first surface; and the second color conversion layer includes laminated N second repeating units, and each of the N second repeating units includes a second barrier layer and a second well layer stacked in the direction from close to the first surface to away from the first surface; where M and N are positive integers, 20<M≤70 and 20<N≤70.

Optionally, the first barrier layer is made of InGaN and the first well layer is made of GaN, or the first barrier layer is made of CaSSe and the first well layer is made of CaSe, or the first barrier layer is made of CdMgZnSe and the first well layer is made of CdZnSe; and the second barrier layer is made of InGaN and the second well layer is made of GaN, or the second barrier layer is made of CaSSe and the second well layer is made of CaSe, or the second barrier layer is made of CdMgZnSe and the second well layer is made of CdZnSe.

Optionally, the first barrier layer and the second barrier layer contain indium, and a concentration of indium in the first barrier layer is different from a concentration of indium in the second barrier layer.

Optionally, the first barrier layer has a thickness ranging from 10 nm to 30 nm, and the first well layer has a thickness ranging from 2 nm to 5 nm; and the second barrier layer has a thickness ranging from 10 nm to 30 nm, and the second well layer has a thickness ranging from 2 nm to 5 nm.

Optionally, each of the at least one light-emitting unit includes a first doped layer, a multi-quantum well layer, and a second doped layer that are stacked sequentially in a direction from close to the color conversion layer to away from the color conversion layer.

Optionally, the light-emitting device further includes a first transflective layer, where the first transflective layer is disposed on a side, away from the light-emitting layer, of the color conversion layer, and the first transflective layer is configured for transmitting light that is converted by the color conversion layer after being emitted by the at least one light-emitting unit and subsequently converted by the color conversion layer, and reflecting light emitted by the at least one light-emitting unit.

Optionally, the light-emitting device further includes a second transflective layer, where the second transflective layer is disposed between the light-emitting layer and the color conversion layer, the second transflective layer covers a sidewall of each of the at least one light-emitting unit, and the second transflective layer is configured for reflecting light that is converted by the color conversion layer after being emitted by the at least one light-emitting unit and subsequently converted by the color conversion layer, and transmitting light emitted by the at least one

Optionally, the light-emitting device further includes a silicon-based driving backplane, where the silicon-based driving backplane is disposed on a side, away from the color conversion layer, of the light-emitting layer and connected to the light-emitting layer.

According to another aspect, a method for manufacturing a light-emitting device is provided. The method includes: providing a light-emitting layer; forming a color conversion layer on a first surface of the light-emitting layer; where the light-emitting layer includes at least one light-emitting unit, the color conversion layer is disposed on the first surface of the light-emitting layer, and the color conversion layer includes multi-quantum wells and is made of inorganic material.

According to another aspect, a display panel is provided, the display panel including a base substrate and a plurality of light-emitting devices arranged in an array on a side of the base substrate, and each of the plurality of light-emitting devices is any one of the light-emitting devices as defined in the above aspect.

According to another aspect, a display device is provided, where the display device includes any one of the light-emitting devices as described in the above aspect and a power supply circuit, and the power supply circuit is configured to supply power to the light-emitting device; or the display device includes the display panel as described in above aspect and the power supply circuit, and the power supply circuit is configured to supply power to the display panel.

The technical solutions according to the present disclosure at least achieve the following beneficial effect: by adopting multi-quantum wells to make a color conversion layer and making the color conversion layer with inorganic material, the problem of poor temperature resistance and poor reliability of the color conversion layer made of organic material is improved.

### BRIEF DESCRIPTION OF DRAWINGS

In order to describe the technical solutions in the embodiments of the present disclosure more clearly, the following briefly introduces the accompanying drawings required for describing the embodiments. Apparently, the accompanying drawings in the following description show merely some embodiments of the present disclosure, and a person skilled in the art can still derive other drawings from these accompanying drawings without creative efforts.

FIG. 1 is a schematic cross-sectional structural diagram of a light-emitting device according to an embodiment of the present disclosure;

FIG. 2 is a schematic plane structural diagram of a light-emitting device according to an embodiment of the present disclosure;

FIG. 3 is a schematic cross-sectional structural diagram of a first color conversion layer and a second color conversion layer according to an embodiment of the present disclosure;

FIG. 4 is a schematic partial cross-sectional structural diagram of a light-emitting device according to an embodiment of the present disclosure;

FIG. 5 is a top view of a raised electrode and a conductive layer according to an embodiment of the present disclosure;

FIG. 6 is a schematic cross-sectional structural diagram of a driving backplane according to an embodiment of the present disclosure;

FIG. 7 is a schematic cross-sectional structural diagram of another light-emitting device according to an embodiment of the present disclosure;

FIG. 8 is a schematic plane structural diagram of another light-emitting device according to an embodiment of the present disclosure;

FIGS. 9 to 11 are schematic cross-sectional structural diagrams of another light-emitting device according to some embodiments of the present disclosure;

FIG. 12 is a top view of another raised electrode and conductive layer according to an embodiment of the present disclosure;

FIG. 13 is a schematic plane structural diagram of another light-emitting device according to an embodiment of the present disclosure;

FIG. 14 is a schematic cross-sectional structural diagram of another light-emitting device according to an embodiment of the present disclosure;

FIG. 15 is a schematic cross-sectional structural diagram of another light-emitting device according to an embodiment of the present disclosure;

FIG. 16 is a schematic cross-sectional structural diagram of another light-emitting device according to an embodiment of the present disclosure;

FIG. 17 is a flow chart of a method for manufacturing a light-emitting device according to an embodiment of the present disclosure;

FIG. 18 is a flow chart of another method for manufacturing a light-emitting device according to an embodiment of the present disclosure;

FIG. 19 is a flow chart of another method for manufacturing a light-emitting device according to an embodiment of the present disclosure;

FIG. 20 is a first part of a flow chart of another method for manufacturing a light-emitting unit according to an embodiment of the present disclosure; and

FIG. 21 is a second part of the flow chart of the another method for manufacturing a light-emitting unit according to an embodiment of the present disclosure.

Reference numerals in the figures are as follows:
1—silicon-based driving backplane, 101—substrate, 102—light shieling layer, 103—first gate layer, 104—second gate layer, 105—third gate layer, 106—first source-drain layer, 107—second source-drain layer, 108—first semiconductor layer, 109—second semiconductor layer, 110—buffer layer, 111—first gate insulating layer, 112—first insulating layer, 113—second gate insulating layer, 114—third gate insulating layer, 115—interlayer dielectric layer, 116—passivation layer, 117—first planarization layer, 118—second planarization layer;
2—light-emitting unit, A—first surface, 2a—first light-emitting unit, 2b—second light-emitting unit, 2c—third light-emitting unit, 201—first pin, 202—second pin, 21—first doped layer, 22—multi-quantum well layer, 23—second doped layer, 24—buffer layer, 25—raised electrode, 26—conductive layer, 27—insulating layer, 27a—first via hole, 27b—second via hole, 28—base, 291—adhesion structure, 292—deadhesion layer, 293—temporary carrier;
3—color conversion layer, 31—first color conversion layer, 32—second color conversion layer, 33—third color conversion layer;
41—first adhesion layer, 42—second adhesion layer, 43—third adhesion layer, 44—fourth adhesion layer; and
5—retaining wall, 61—first transflective layer 62, second transflective layer.

### DETAILED DESCRIPTION

To make the objectives, technical solutions, and advantages of the present disclosure clearer, the embodiments of the present disclosure are further described hereinafter with reference to the accompanying drawings.

The terminology used in the embodiments of the present disclosure is only for the purpose of illustrating the embodiments of the present disclosure and is not intended to limit the present disclosure. Unless otherwise defined, the technical terms or scientific terms used in the embodiments of the present disclosure have ordinary meanings as understood by the ordinary skill in the art to which the present disclosure belongs. The terms “first,” “second,” “third,” and the like used in the description and claims of the present disclosure do not indicate any order, quantity, or importance, but are merely used to distinguish different components. Similarly, terms such as “a” or “an” do not indicate the quantity limit, but indicate the existence of at least one. The terms “comprise,” “include,” and the like are intended to indicate that the elements or objects before the terms cover the elements, objects, or equivalents thereof listed behind the terms, without excluding other elements or objects. The positional terms in the present disclosure, such as “top,” “bottom,” “upper,” “lower,” “left,” “right,” and the like, are only referred to the directions in accompanying drawings, and therefore, the positional terms used herein are intended to better and more clearly illustrate and get across the embodiments of the present disclosure, but are not intended to indicate or imply that the device or element referred to must have a particular orientation, be constructed and operated in a particular orientation, and therefore cannot be interpreted as a limitation to the embodiments of the present disclosure.

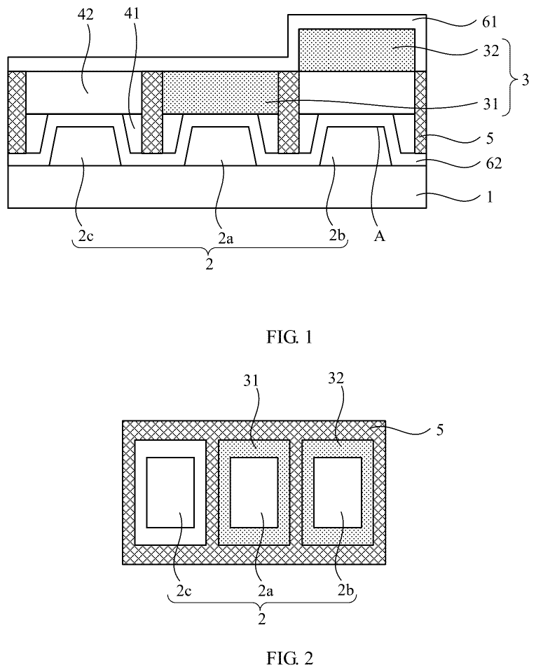

FIG. 1 is a schematic cross-sectional structural diagram of a light-emitting device according to an embodiment of the present disclosure. The light-emitting device includes a light-emitting layer and a color conversion layer 3. The light-emitting layer includes a plurality of light-emitting units 2, and the color conversion layer 3 is disposed on a first surface A of the light-emitting layer. The color conversion layer 3 includes multi-quantum wells and is made of inorganic material. In the related art, the color conversion layer includes a plurality of quantum dot color conversion units and is made of organic material, such that the color conversion layer has the problem of poor temperature resistance and poor reliability. In the embodiments of the present disclosure, by adopting multi-quantum wells to make the color conversion layer and forming the color conversion layer with inorganic material, the temperature resistance and the reliability are improved.

In addition, because the color conversion layer including a plurality of quantum dot color conversion units in the related art has a larger thickness, and approximately ranges from 3 to 10 μm, whereas the thickness of the color conversion layer of inorganic multi-quantum wells in the embodiments of the present disclosure is smaller, which is less than 1 μm, and the color conversion layer of the inorganic multi-quantum wells in the embodiments of the present disclosure is also conducive to the lightening and thinning of the product.

Illustratively, as shown in FIG. 1, the color conversion layer 3 includes a first color conversion layer 31 and a second color conversion layer 32 stacked sequentially in a direction from close to the light-emitting layer to away from the light-emitting layer. The first color conversion layer 31 is configured to convert light emitted by the light-emitting unit 2 to light of a first color, and the second color conversion layer 32 is configured to convert light emitted by the light-emitting unit 2 to light of a second color. The plurality of light-emitting units 2 includes a first light-emitting unit 2a, a second light-emitting unit 2b, and a third light-emitting unit 2c.

FIG. 2 is a schematic plane structural diagram of a light-emitting device according to an embodiment of the present disclosure. As shown in FIG. 2, an orthographic projection of the first light-emitting unit 2a on the first surface A is at least partially overlapped with an orthographic projection of the first color conversion layer 31 on the first surface A, and an orthographic projection of the second light-emitting unit 2b on the first surface A is at least partially overlapped with an orthographic projection of the second color conversion layer 32 on the first surface A. Each of the first color conversion layer 31 and the second color conversion layer 32 includes a multiple-quantum well and is made of inorganic material.

In the embodiments of the present disclosure, the first color conversion layer 31 and the second color conversion layer 32 are disposed in different layers in consideration of the formation process of the multi-quantum wells. Therefore, a whole layer of the first multi-quantum wells corresponding to the first color conversion layer 31 and a whole layer of the second multi-quantum wells corresponding to the second color conversion layer 32 may be first respectively prepared to avoid a lattice mismatch, and then the whole layer of the first multi-quantum wells and the whole layer of the second multi-quantum wells are fixed to the first surface A, such as by an adhesion method, and respectively etched to form the first color conversion layer 31 and the second color conversion layer 32. The color conversion layer in the embodiments of the present disclosure may be formed by means of etching, and thus a high-resolution display can be achieved due to the high precision of the etching process.

Optionally, the first color is red and the second color is green.

Optionally, each of the plurality of light-emitting units 2 is configured to emit blue light. Together with different color conversion layers, such as the first color conversion layer 31 and the second color conversion layer 32, a color display can be achieved.

Optionally, as shown in FIG. 1, in the light-emitting device, the plurality of light-emitting units 2 emit blue light. The blue light emitted by part of the light-emitting units 2, such as the first light-emitting unit 2a, passes through the first color conversion layer 31, the blue light emitted by part of the light-emitting units 2, such as the second light-emitting unit 2b, passes through the second color conversion layer 32, and the light emitted by another part of the light-emitting units, such as the third light-emitting unit 2c, does not pass through a color conversion layer, and thus remains blue after emission.

Optionally, as shown in FIG. 1, the three light-emitting units 2 are arranged along one direction, and in other possible ways, the three light-emitting units 2 are arranged in a triangle shape.

Optionally, orthographic projection areas of the first light-emitting unit 2a, the second light-emitting unit 2b, and the third light-emitting unit 2c on the first surface A may be different, thereby facilitating the modulation of the output amount of light of different colors.

As shown in FIG. 1, the light-emitting device further includes a first adhesion layer 41 and a second adhesion layer 42. The first adhesion layer 41 is disposed between the plurality of light-emitting units 2 and the color conversion layer 3, and the second adhesion layer 42 is disposed between the first color conversion layer 31 and the second color conversion layer 32. Both of the first adhesion layer 41 and the second adhesion layer 42 are made of transparent material. The first adhesion layer 41 serves to bond the plurality of light-emitting units 2 and the first color conversion layer 31, and the second adhesion layer 42 serves to bond the first color conversion layer 31 and the second color conversion layer 32. Moreover, because both the first adhesion layer 41 and the second adhesion layer 42 are made of transparent material, there is less influence on the light output.

Optionally, a surface of the first adhesion layer 41 in contact with the first color conversion layer 31 is planar, and a surface of the second adhesion layer 42 in contact with the second color conversion layer 32 is planar. Because the surface of the first adhesion layer 41 in contact with the first color conversion layer 31 is planar, the whole layer of the first multi-quantum wells corresponding to the first color conversion layer 31 can be adhered to a side of the light-emitting unit 2 flat, thereby facilitating subsequent etching out the first color conversion layer 31. Because the surface of the second adhesion layer 42 in contact with the second color conversion layer 32 is planar, the whole layer of the second multi-quantum wells corresponding to the second color conversion layer 32 can be adhered to a side of the light-emitting unit 2 flat, thereby facilitating subsequent etching out the second color conversion layer 32.

Optionally, the first adhesion layer 41 and the second adhesion layer 42 have a greater transmittance, for example, greater than 95%.

Optionally, the first adhesion layer 41 and the second adhesion layer 42 are made of organic material, such as BCB (benzocyclobutene), photoresist, polyimide, acrylic, polyacrylic acid, silicone, and the like. The first adhesion layer 41 and the second adhesion layer 42 may be also made of inorganic material, such as silicon oxide, silicon nitride, aluminum oxide, and the like.

Illustratively, as shown in FIG. 1, the light-emitting device further includes a driving backplane 1, and the driving backplane 1 is disposed on a side, away from the color conversion layer 3, of the light-emitting layer and connected to the light-emitting layer. The driving backplane 1 is configured to control the plurality of light-emitting units 2 disposed on the driving backplane 1. In other possible embodiments, the light-emitting device may also do not include the driving backplane 1.

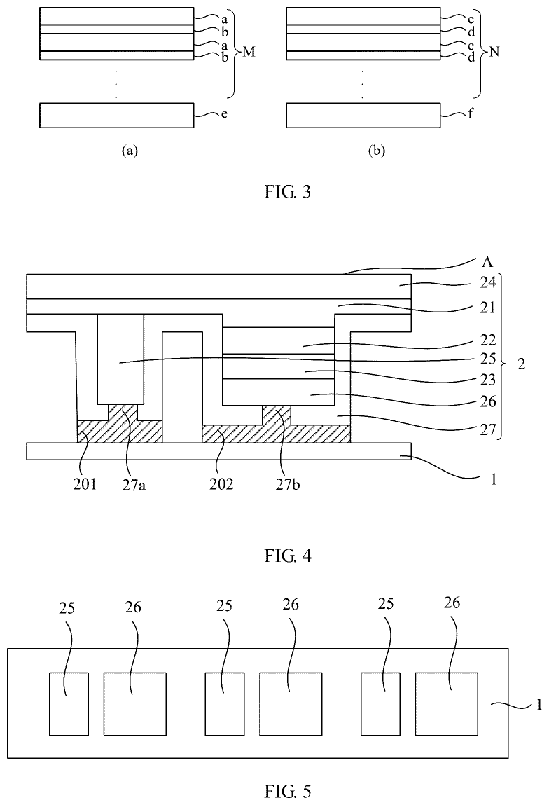

FIG. 3 is a schematic cross-sectional structural diagram of a first color conversion layer and a second color conversion layer according to an embodiment of the present disclosure. As shown in part (a) of FIG. 3, the first color conversion layer 31 includes laminated M first repeating units, and the first repeating unit includes a first barrier layer a and a first well layer b stacked in a direction from close to the first surface A to away from the first surface A. As shown in part (b) of FIG. 3, the second color conversion layer 32 includes laminated N second repeating units, and the second repeating unit includes a second barrier layer c and a second well layer d stacked in the direction from close to the first surface A to away from the first surface A. M and N are both positive integers, 20<M≤70, and 20<N≤70, which enables the first color conversion layer 31 and the second color conversion layer 32 to have a better absorbance and avoids over-absorption of the first color conversion layer 31 and the second color conversion layer 32 and the influence on light output due to the excessively large M and N. Optionally, M is 30, 40, 50, 60, or 70, and N is 30, 40, 50, 60, or 70.

Optionally, the first barrier layer a is made of InGaN and the first well layer b is made of GaN, or the first barrier layer a is made of CaSSe and the first well layer b is made of CaSe, or the first barrier layer a is made of CdMgZnSe and the first well layer b is made of CdZnSe. The second barrier layer c is made of InGaN and the second well layer d is made of GaN, or the second barrier layer c is made of CaSSe and the second well layer d is made of CaSe, or the second barrier layer c is made of CdMgZnSe and the second well layer d is made of CdZnSe. The multi-quantum wells composed of the barrier layer and the well layer made of the above material can convert the light emitted by the light-emitting unit into different colors, thereby achieving a color display.

Optionally, the first barrier layer a and the second barrier layer c contain indium, and a concentration of indium in the first barrier layer a is different from a concentration of indium in the second barrier layer c. By adjusting the concentrations of indium in the first barrier layer a and the second barrier layer c, the first color conversion layer 31 and the second color conversion layer 32 are able to convert the light emitted by the light-emitting unit 2 into light of different colors, thereby achieving a display.

Optionally, the first barrier layer a has a thickness ranging from 10 nm to 30 nm, such as 10 nm, 20 nm, or 30 nm, and the first well layer b has a thickness ranging from 2 nm to 5 nm, such as 2 nm, 3 nm, 4 nm, or 5 nm. The second barrier layer c has a thickness ranging from 10 nm to 30 nm, such as 10 nm, 20 nm, or 30 nm, and the second well layer d has a thickness ranging from 2 nm to 5 nm, such as 2 nm, 3 nm, 4 nm, or 5 nm. For the first barrier layer a or the second barrier layer c, if the thickness thereof is too large, the absorption rate of the first color conversion layer 31 or the second color conversion layer 312 for the light (e.g., blue light) emitted by the light-emitting unit 2 may be affected.

Optionally, in conjunction with FIG. 1 and part (a) of FIG. 3, the first color conversion layer 31 further includes a barrier layer e disposed on a side, close to the first surface A, of the laminated M first repeating units. In conjunction with FIG. 1 and part (b) of FIG. 3, the second color conversion layer 32 further includes a barrier layer f disposed on a side, close to the first surface A, of the laminated N first repeating units. Optionally, the barrier layer e has a thickness greater than the thickness of the first barrier layer a, for example, in the case that the thickness of the first barrier layer a is 10 nm, the thickness of the barrier layer e is 20 nm; and the thickness of the barrier layer f is greater than the thickness of the second barrier layer c, for example, the thickness of the second barrier layer c is 10 nm, and the thickness of the barrier layer f is 20 nm. The thicker barrier layer e can provide better protection for the first well layer b adjacent to the barrier layer e, and the thicker barrier layer f can provide better protection for the second well layer d adjacent to the barrier layer f.

Illustratively, as shown in FIG. 1, the light-emitting device further includes a first transflective layer 61. The first transflective layer 61 is disposed on a side, away from the light-emitting layer, of the color conversion layer 3, and the first transflective layer 61 is configured for transmitting the light of the first color and the second color and reflecting the light emitted by the light-emitting unit 2. The provision of the first transflective layer 61 improves the utilisation of the light emitted by the light emitting unit 2 by the color conversion layer 3.

Optionally, the first transflective layer 61 includes a plurality of first sub-layers and a plurality of second sub-layers, the plurality of first sub-layers and the plurality of second sub-layers are alternately stacked, and a refractive index of each of the plurality of first sub-layers is larger than a refractive index of each of the plurality of second sub-layers. The first sub-layers are made of silicon nitride, niobium pentoxide, or titanium dioxide, and the second sub-layers are made of silicon oxide. The first sub-layer made of silicon nitride, niobium pentoxide, or titanium dioxide has a larger refractive index of about 1.7 or more, and the second sub-layer made of silicon oxide has a smaller refractive index approximately ranging from 1.5 to 1.6. Optionally, such a first transflective layer 61 formed by using a gel of two types of material with different refractive indices is also referred to as a Distributed Bragg Reflection (DBR) mirror.

Optionally, as shown in FIG. 1, the first transflective layer 61 is in the form of a step at the side wall of the second color conversion layer 32, but the portion of the first transflective layer 61 that corresponds to the light output region corresponding to each of the light-emitting units 2 is planar, and thus such design does not affect the light output of the light-emitting units.

In other possible embodiments, the first transflective layer 61 is planar in a whole layer. Correspondingly, the light-emitting device further includes a fourth adhesion layer between the first transflective layer 61 and the second color conversion layer 32 to fill up and make even the space below the planar first transflective layer 61 and without the color conversion layer.

Illustratively, as shown in FIG. 1, the light-emitting device further includes a second transflective layer 62, the second transflective layer 62 is disposed between the plurality of light-emitting units 2 and the color conversion layer 3, and the second transflective layer 62 is configured for reflecting the light of the first color and the second color and transmitting the light emitted by the light-emitting units 2. By setting the second transflective layer 62, the transmittance of the light emitted by the light-emitting units 2 is increased and the light that is converted by the color conversion layer 3 is prevented from leaking from one side of the light-emitting units 2, thereby increasing the light-emitting efficiency of the light-emitting device.

Optionally, the second transflective layer 62 includes a plurality of third sub-layers and a plurality of fourth sub-layers, and the plurality of third sub-layers and the plurality of fourth sub-layers are alternately stacked, with a refractive index of each of the plurality of third sub-layers being greater than a refractive index of each of the plurality of fourth sub-layers. The third sub-layer is made of silicon nitride, niobium oxide, or titanium dioxide, and the fourth sub-layer is made of silicon oxide. The third sub-layer made of silicon nitride, niobium oxide, or titanium dioxide has a larger refractive index of about 1.7 or more, and the fourth sub-layer made of silicon oxide has a smaller refractive index approximately ranging from 1.5 to 1.6. Optionally, such a second transflective layer 62, formed by using a gel of two types of material with different refractive indices, is also referred to as a Distributed Bragg Reflection mirror.

Optionally, the light-emitting device may include both the first transflective layer 61 and the second transflective layer 62 as shown in FIG. 1; or the light-emitting device may also only include the first transflective layer 61 or the second transflective layer 62.

Illustratively, as shown in FIG. 1, the light-emitting device further includes a barrier wall structure 5. Combining FIGS. 1 and 2, the barrier wall structure 5 is disposed between different light-emitting units 2 and between color conversion layers corresponding to different colors, so as to separate light of different colors and prevent light crosstalk and other problems.

Optionally, the barrier wall structure 5 is made of the black matrix material, such as carbon black and resin material, and the barrier wall structure 5 is able to absorb the light, which is emitted by the light-emitting unit 2 and is directed to the adjacent light-emitting unit 2 or the light between adjacent color conversion layers, thereby preventing light crosstalk; or the barrier wall structure 5 is made of metal material such as copper, which can not only play a role in preventing light crosstalk, but also reflect the light, which is directed to the barrier wall structure 5, back to the region above the corresponding light-emitting unit 2, such as the corresponding color conversion layer or the transparent adhesion layer, which is beneficial to improve the light output rate.

FIG. 4 is a schematic partial cross-sectional structural diagram of a light-emitting device according to an embodiment of the present disclosure, and FIG. 4 shows a schematic cross-sectional structural diagram of a driving backplane and a light-emitting unit in the light-emitting device shown in FIG. 1. As shown in FIG. 4, each of the plurality of light-emitting units includes one first pin 201 and one second pin 202. The first pin 201 and the second pin 202 are disposed on a side, away from the color conversion layer 3, of the light-emitting unit 2. The light-emitting unit 2 may be electrically connected to such as a driving circuit in a silicon-based driving backplane by the first pin 201 and the second pin 202.

Optionally, a pair of pins includes one first pin 201 and one second pin 202, and the number of light-emitting units 2 in the light-emitting device is the same as the number of pairs of pins.

Optionally, in a light-emitting device, there are three light-emitting units, each of the three light-emitting units has a pair of pins, and each of the three light-emitting units 2 is electrically connected to the driving backplane via a pair of pins.

Illustratively, the light-emitting units in the embodiments shown in FIGS. 1 and 4 are miniature light-emitting units. In other possible embodiments, the light-emitting units are mini-light-emitting units or light-emitting units of other sizes.

The structures of the light-emitting unit of the embodiment shown in FIGS. 1 and 4 are illustratively described below. As shown in FIG. 4, in a direction from close to the color conversion layer 3 to away from the color conversion layer 3, the light-emitting unit 2 includes a first doped layer 21, a multi-quantum well layer 22, and a second doped layer 23 that are stacked sequentially. The first doped layer 21 is electrically connected to a first pin 201, and the second doped layer 23 is electrically connected to a second pin 202.

Optionally, the first doped layer 21 may be an N-type doped layer and the second doped layer 23 may be a P-type doped layer. Accordingly, the raised electrode 25 may be referred to as an N-type electrode, the first pin 201 may be referred to as an N-Pad, and the second pin 202 may be referred to as a P-Pad.

Optionally, the material of the first doped layer 21 may include N-type gallium nitride (GaN), and the first doped layer 21 is denoted as N-GaN. The material of the second doped layer 23 includes P-type gallium nitride (GaN), and the second doped layer 23 is denoted as P-GaN.

Optionally, the first doped layer 21 has a thickness of about 2 μm, the second doped layer 23 has a thickness of about 0.2 μm, and the multi-quantum well layer 22 has a thickness of about 0.05 μm.

Optionally, as shown in FIG. 4, the light-emitting unit 2 further includes a buffer layer 24. The buffer layer 24 is disposed on a side, close to the color conversion layer 3, in the light-emitting unit 2. The material of the buffer layer 24 may be GaN. Optionally, the thickness of the buffer layer 24 is about 2 μm. In other possible embodiments, the light-emitting unit 2 may also include a thinner buffer layer 24 or without buffer layer 24. The thinning or removal of the buffer layer 24 facilitates the lightening and thinning of the product.

Illustratively, in conjunction with FIGS. 1 and 4, the light-emitting unit 2 further includes a raised electrode 25, a conductive layer 26, and an insulating layer 27. The raised electrode 25 is connected to the first doped layer 21, the conductive layer 26 is disposed on the side, away from the color conversion layer 3, of the second doped layer 23, and the insulating layer 27 is disposed on a side, close to the backplane 1, of the raised electrode 25 and the conductive layer 26. The insulating layer 27 is provided with a first via hole 27a and a second via hole 27b. The first via hole 27a is configured to expose the raised electrode 25, such that the raised electrode 25 and the first pin 201 are connected through the first via hole 27a. The second via hole 27b is configured to expose the conductive layer 26, such that the conductive layer 26 and the second pin 202 are connected through the second via hole 27b.

Optionally, the material of the conductive layer 26 may be indium tin oxide (ITO); the insulating layer 27 may be a passivation layer (PVX), and the material of the insulating layer 27 may be silicon oxide or silicon nitride.

Optionally, the conductive layer 26 has a thickness ranging from 100 nm to 140 nm, such as 100 nm, 110 nm, 120 nm, 130 nm, or 140 nm.

Optionally, the insulating layer 27 has a thickness ranging from 500 nm to 1000 nm, such as 500 nm, 600 nm, 700 nm, 800 nm, 900 nm, or 1000 nm.

Optionally, the raised electrode 25 includes a plurality of metal layers stacked sequentially, such as titanium, aluminum, nickel, and gold stacked sequentially; or cadmium, platinum, and gold stacked sequentially.

Optionally, the first pin 201 or the second pin 202 includes a plurality of metal layers stacked sequentially, such as titanium, aluminum, nickel, and gold stacked sequentially; or cadmium, platinum, and gold stacked sequentially.

FIG. 5 is a top view of a raised electrode and a conductive layer according to an embodiment of the present disclosure. As shown in FIG. 5, in each light-emitting unit 2, both an orthographic projection of the raised electrode 25 on the first surface A and an orthographic projection of the conductive layer 26 on the first surface A are rectangular. Optionally, the orthographic projection of the raised electrode 25 on the first surface A and the orthographic projection of the conductive layer 26 on the first surface A may have other shapes, such as circles, which is not limited in the present disclosure.

Optionally, in conjunction with FIGS. 4 and 5, an area of the orthographic projection of the raised electrode 25 on the first surface A of the driving backplane 1 is larger than an area of an orthographic projection of the first via hole 27a on the first surface A, and an area of an orthographic projection of the first pin 201 on the first surface A is larger than the area of the orthographic projection of the first via hole 27a on the first surface A, so as to ensure that the raised electrode 25 and the first pin 201 may be stably connected. An area of the orthographic projection of the conductive layer 26 on the first surface A is larger than an area of an orthographic projection of the second via hole 27b on the first surface A, and an area of the orthographic projection of the second pin 202 on the first surface A is larger than the area of the orthographic projection of the second via hole 27b on the first surface A, so as to ensure that the conductive layer 26 and the second pin 202 can be stably connected.

Optionally, as shown in FIG. 4, the area of the orthographic projection of the raised electrode 25 on the first surface A is less than the area of the orthographic projection of the first pin 201 on the first surface A, and the area of the orthographic projection of the conductive layer 26 on the first surface A is less than the area of the orthographic projection of the second pin 202 on the first surface A.

Optionally, the area of the orthographic projection of the raised electrode 25 on the first surface A may be greater than the area of the orthographic projection of the first pin 201 on the first surface A, and the area of the orthographic projection of the conductive layer 26 on the first surface A may be greater than the area of the orthographic projection of the second pin 202 on the first surface A.

Illustratively, as shown in FIG. 1, the driving backplane 1 is a silicon-based driving backplane. The width of trace lines in the silicon-based driving backplane is small, so the light-emitting device formed by using the silicon-based driving backplane has a high PPI (Pixels Per Inch).

Illustratively, the silicon-based driving backplane 1 may also be replaced by other driving backplanes, such as glass-based driving backplanes, including LTPO (Low-temperature Polycrystalline Oxide) backplanes and LTPS (Low-Temperature Poly-Silicon) backplanes.

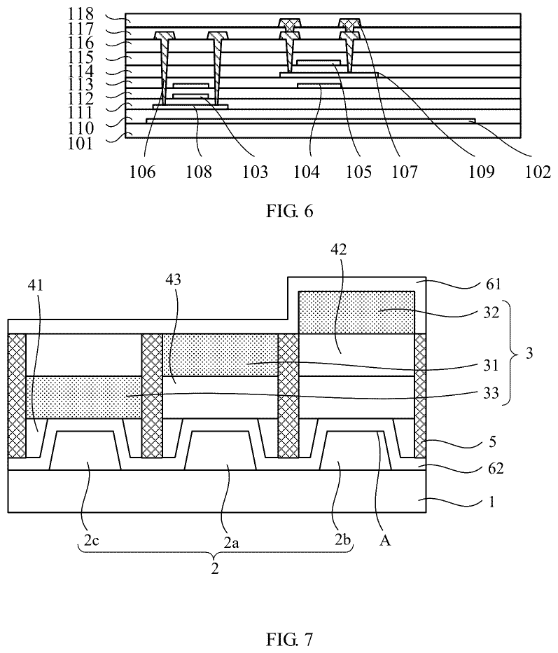

FIG. 6 is a schematic cross-sectional structural diagram of a driving backplane according to an embodiment of the present disclosure. As shown in FIG. 6, a glass-based driving backplane is an LTPO backplane. The following is an illustrative description of various layer structures of the LTPO backplane in the embodiment shown in FIG. 6.

Illustratively, as shown in FIG. 6, the driving backplane includes a light shieling layer 102, a buffer layer 110, a first semiconductor layer 108, a first gate insulating layer 111, a first gate layer 103, a first insulating layer 112, a second gate layer 104, a second gate insulating layer 113, a second semiconductor layer 109, a third gate insulating layer 114, a third gate layer 105, an interlayer dielectric layer 115, a passivation layer 116, a first source-drain layer 106, a first planarization layer 117, a second source-drain layer 107, and a second planarization layer 118.

Illustratively, the substrate 101 may be any transparent substrate, such as a glass substrate, a quartz substrate, a plastic substrate, other transparent rigid substrate, or other transparent flexible substrate, and the substrate 101 may be a single-layer structure or a multi-layer structure. Taking the multi-layer structure as an example, the substrate 101 includes a first PI (polyimide) layer, a first protective layer, a second PI (polyimide) layer, and a second protective layer that are stacked sequentially from the bottom to the top. The two protective layers are configured to protect the PI layers and prevent the subsequent process from damaging the PI layers. The second protective layer is further covered with a buffer layer that blocks water oxygen and alkaline ions.

Illustratively, the material of which the light shielding layer 102 is made may be a metallic material, including but not limited to molybdenum, aluminum, titanium, copper, etc., and the light shielding layer 102 reduces the amount of light directed to the TFT (Thin Film Transistor) and is able to conduct electricity at the same time. The light shielding layer 102 may also be referred to as a BSM (bottom shield metal) layer.

Illustratively, the first semiconductor layer 108 is made of low-temperature polysilicon material, and the second semiconductor layer 109 is made of metal oxide semiconductor material such as IGZO (Indium Gallium Zinc Oxide).

Illustratively, the material of which the first gate insulating layer 111, the first insulating layer 112, the second gate insulating layer 113, the third gate insulating layer 114, and the interlayer dielectric layer 115 are made may include a silicon oxide, a silicon nitride, or a silicon nitride oxide, or the like.

Illustratively, the material of which the first gate layer 103, the second gate layer 104, and the third gate layer 105 are made is a metallic material, such as one or more of molybdenum, copper, aluminum, and titanium.

Illustratively, the material of which the passivation layer 116 is made may include a silicon oxide or a silicon nitride.

Illustratively, the first planarization layer 117 and the second planarization layer 118 are made of organic insulating material, such as resin.

In other possible embodiments, the driving backplane may also be an LTPS (Low-Temperature Poly-Silicon) backplane. For the LTPS backplane, the driving backplane includes a substrate, a first gate layer, a first gate insulating layer, a first semiconductor layer, a second gate insulating layer, a second gate layer, an interlayer dielectric layer, a passivation layer, a first source-drain layer, and a first planarization layer that are stacked sequentially. The material used to make each layer is the same as the material used for the previous LTPO backplane and is not repeated herein.

In another possible embodiment, each light-emitting unit 2 is configured to emit ultraviolet light. The ultraviolet light may also be converted into light of different colors, such as a first color, a second color, and a third color, after passing through the color conversion layers of different multi-quantum wells. Because the color conversion layer of the multi-quantum wells absorbs more ultraviolet light than blue light, the light efficiency is improved by setting the light-emitting unit 2 to emit ultraviolet light.

FIG. 7 is a schematic cross-sectional structural diagram of another light-emitting device according to an embodiment of the present disclosure. Compared to the embodiment shown in FIG. 1, in the embodiment shown in FIG. 7, the color conversion layer 3 further includes a third color conversion layer 33. The third color conversion layer 33 is disposed on the side, away from the second color conversion layer 32, of the first color conversion layer 31, the third color conversion layer 33 is configured for converting the light emitted by the light-emitting unit 2 to light of a third color, and an orthographic projection of the third color conversion layer 33 on the first surface A is at least partially overlapped with an orthographic projection of the third light-emitting unit 2c on the first surface A. The light emitted by the light-emitting unit 2 in the embodiment shown in FIG. 7 is ultraviolet light, and thus the third color conversion layer 33 is also required to convert the light emitted by the third light-emitting unit 2c to light of the third color so as to achieve a color display.

Optionally, in the embodiment shown in FIG. 7, the light-emitting device further includes a third adhesion layer 43, and the third adhesion layer 43 is disposed between the third color conversion layer 33 and the first color conversion layer 31. The first adhesion layer 41 is configured to bond the plurality of light-emitting units 2 and the color conversion layer 3, i.e., to bond the plurality of light-emitting units 2 and the third color conversion layer 33. The second adhesion layer 42 is configured to bond the first color conversion layer 31 and the second color conversion layer 32. The third adhesion layer 43 is configured to bond the third color conversion layer 33 and the first color conversion layer 31.

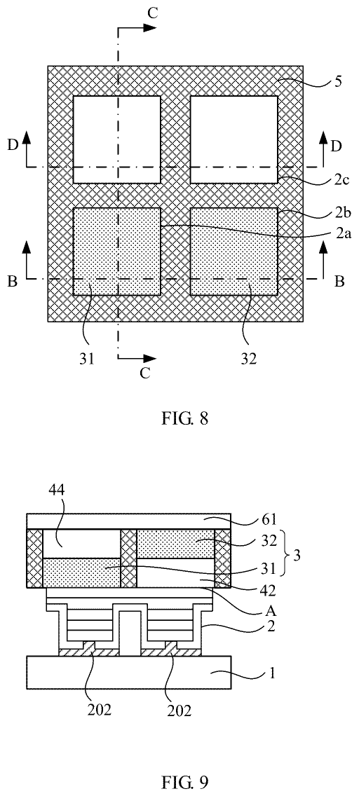

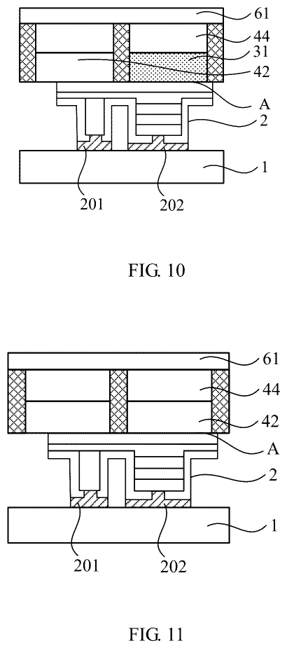

FIG. 8 is a schematic planar structural diagram of another light-emitting device according to an embodiment of the present disclosure, FIGS. 9 to 11 are schematic cross-sectional structural diagrams of the another light-emitting device according to some embodiments of the present disclosure, and FIGS. 9 to 11 are schematic cross-sectional structural diagrams respectively along a section line BB, a section line CC, and a section line DD shown in FIG. 8. Compared to the embodiment shown in FIG. 1, in the embodiments shown in FIGS. 8 to 11, the light-emitting device includes a first light-emitting unit 2a, a second light-emitting unit 2b, and a third light-emitting unit 2c that are adjacent. The first light-emitting unit 2a, the second light-emitting unit 2b, and the third light-emitting unit 2c form an integrative structure and share one first pin 201. Herein, in conjunction with FIG. 4, the first light-emitting unit 2a, the second light-emitting unit 2b, and the third light-emitting unit 2c forming an integrative structure means that the first light-emitting unit 2a, the second light-emitting unit 2b, and the third light-emitting unit 2c can share a part of the film layer structure (e.g., the buffer layer 24 and the first doped layer 21), and thus the first light-emitting unit 2a, the second light-emitting unit 2b, and the third light-emitting unit 2c can be formed as a connected integrative structure; whereas, for a part of the film layer structure which cannot be shared (e.g. multi-quantum well layer 22 and second doped layer 23, etc.) are patterned to distinguish the first light-emitting unit 2a, the second light-emitting unit 2b, and the third light-emitting unit 2c. The design of the three light-emitting units sharing one first pin 201 is conducive to reducing the size of the light-emitting device.

Optionally, the first doped layers 21 and the buffer layers 24 of the first light-emitting unit 2a, the second light-emitting unit 2b, and the third light-emitting unit 2c share a common structural layer. The other structural layers in the light-emitting unit 2 are referred to the foregoing descriptions and are not repeated herein.

Optionally, one raised electrode 25 and three conductive layers 26 are respectively connected to one first pin 201 and three second pins 202.

Optionally, the light emitted by the light-emitting unit is blue, as shown in FIGS. 8 to 11. The top view of the light-emitting unit is in the shape of “ [symbol] ”. The upper left portion in FIG. 8 corresponds to the first pin 201 and the raised electrode 25, and no light is emitted from the region corresponding to the upper left portion; and the upper right portion in FIG. 8 corresponds to the second pin 202 but does not have a color conversion layer, and in the region corresponding to the upper right portion, the light emitted by the light-emitting unit 2, such as blue light, does not pass through the first color conversion layer 31 or the second color conversion layer 32. The lower left portion in FIG. 8 corresponds to the second pin 202 and has the first color conversion layer 31, and in the region corresponding to the lower left portion, the light emitted by the first light-emitting unit 2a is converted to light of a first color, such as red light, after passing through the first color conversion layer 31; and the lower right portion in FIG. 8 corresponds to the second pin 202 and has a second color conversion layer 32, and in the region corresponding to the lower right portion, the light emitted by the second light-emitting unit 2b is converted to light of a second color, such as green light, after passing through the second color conversion layer 32.

Optionally, in the embodiments shown in FIGS. 8 to 11, the light-emitting device further includes a fourth adhesion layer 44, and the fourth adhesion layer 44 is configured to fill up and make even regions other than the raised second color conversion layer 32. The fourth adhesion layer 44 is made of transparent material. Correspondingly, in the embodiments shown in FIGS. 8 to 11, the first transflective layer 61 is planar.

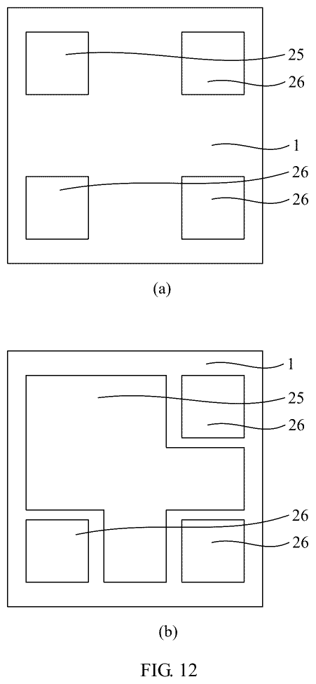

FIG. 12 is a top view of another raised electrode and conductive layer according to an embodiment of the present disclosure. As shown in part (a) of FIG. 12, both the orthographic projections of the raised electrode 25 and the conductive layer 26 on the first surface A may be square. As shown in part (b) of FIG. 12, the raised electrode 25 may also include a body, and a first extension portion and a second extension portion which are connected to the body. Optionally, as shown in part (b) of FIG. 12, the first extension portion is located between the conductive layer 26 in the upper right corner and the conductive layer 26 in the lower right corner, and the second extension portion is located between the conductive layer 26 in the lower left corner and the conductive layer 26 in the lower right corner. Optionally, orthographic projections of the body, the first extension, and the second extension on the first surface A may be all in the shape of squares as shown in part (b) of FIG. 12, or in the shape of other shapes, which are not limited in the present disclosure.

Optionally, as shown in part (b) of FIG. 12, the orthographic projection of the raised electrode 25 on the first surface A is larger than the orthographic projection of the conductive layer 26 on the first surface A. The design maximizes the orthographic projection area of the raised electrode 25 on the first surface A, thereby increasing the current extension capability.

In other possible embodiments, the area of the orthographic projection of the raised electrode 25 on the first surface A is larger than the area of the orthographic projection of the first pin 201 on the first surface A. Because the raised electrode 25 has a larger area of orthographic projection and a larger cross-sectional area, the internal resistance of the light-emitting device is reduced, the voltage drop is reduced, and the light output is increased.

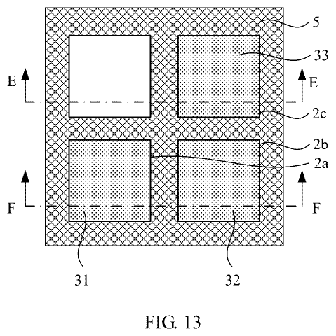

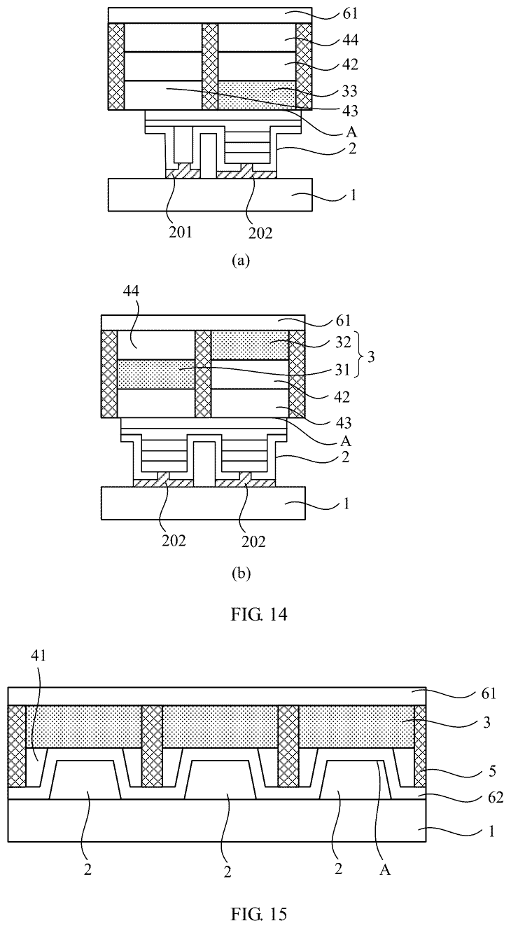

FIG. 13 is a schematic planar structural diagram of another light-emitting unit according to an embodiment of the present disclosure, FIG. 14 is a schematic cross-sectional structural diagram of another light-emitting unit according to an embodiment of the present disclosure, and part (a) and part (b) of FIG. 14 are schematic cross-sectional structural diagrams respectively along a section line EE and a section line FF shown in FIG. 13. Compared with the embodiments shown in FIGS. 8 to 11, in the embodiments shown in FIGS. 13 and 14, the light emitted by the light-emitting unit is ultraviolet light, and the color conversion layer 3 further includes a third color conversion layer 33. The top view of the light-emitting unit is in the shape of “ [symbol] ”, in which the upper left portion corresponds to the first pin 201 and the raised electrode 25, and no light is emitted in the region corresponding to the upper left portion; the upper right portion corresponds to the second pin 202 and has the third color conversion layer 33, and in the region corresponding to the upper right portion, the light emitted by the third light-emitting unit 2c, such as ultraviolet light, is converted to light of a third color, such as blue, after passing through the third color conversion layer 33; the lower left portion corresponds to the second pin 202 and has a first color conversion layer 31, and in the region corresponding to the lower left portion, the light emitted by the first light-emitting unit 2a is converted to light of a first color, such as red light, after passing through the first color conversion layer 31; and the lower right portion corresponds to the second pin 202 and has a second color conversion layer 32, and in the region corresponding to the lower right portion, the light emitted by the second light-emitting unit 2b is converted to light of a second color, such as green light, after passing through the second color conversion layer 32. In this way, the light-emitting device is capable of emitting light of different colors in different regions, thereby achieving a color display function.

FIG. 15 is a schematic cross-sectional structural diagram of another light-emitting device according to an embodiment of the present disclosure. As shown in FIG. 15, the light-emitting device includes a plurality of light-emitting units 2 and a color conversion layer 3. The color conversion layer 3 is provided to convert light emitted from the plurality of light-emitting units 2 to other colors to achieve a monochromatic display.

Optionally, in the embodiment shown in FIG. 15, the light-emitting device further includes a second transflective layer 62, and the second transflective layer 62 covers sidewalls of the plurality of light-emitting units 2, such that as much light emitted by the light-emitting units 2 as possible is enabled to pass through the second transflective layer 62. Here, in conjunction with FIG. 4, the second transflective layer 62 covering the sidewalls of the plurality of light-emitting units 2 means that the second transflective layer 62 covers all the sidewalls in the plurality of light-emitting units 2 except for a sidewall located between the first pin 201 and the second pin 202.

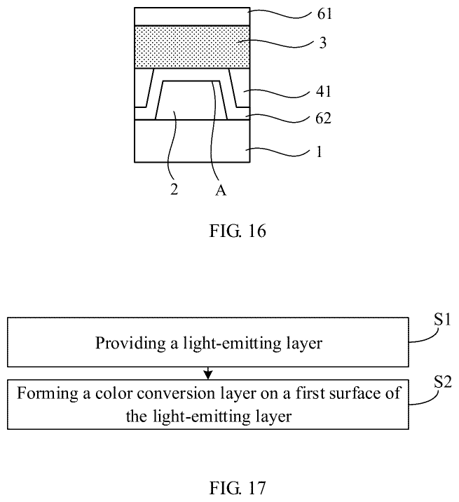

FIG. 16 is a schematic cross-sectional structural diagram of another light-emitting device according to an embodiment of the present disclosure. As shown in FIG. 16, the light-emitting device includes one light-emitting unit 2 and a color conversion layer 3. The color conversion layer 3 is provided to convert the light emitted by the light-emitting unit 2 to other colors to achieve the monochromatic display.

FIG. 17 is a flow chart of a method for manufacturing a light-emitting device according to an embodiment of the present disclosure. As shown in FIG. 17, the method includes the following processes.

In process S1, a light-emitting layer is provided.

In process S2, a color conversion layer is formed on a first surface of the light-emitting layer;

where the light-emitting layer includes at least one light-emitting unit, the color conversion layer is disposed on the first surface of the light-emitting layer, and the color conversion layer includes multi-quantum wells and is made of inorganic material.

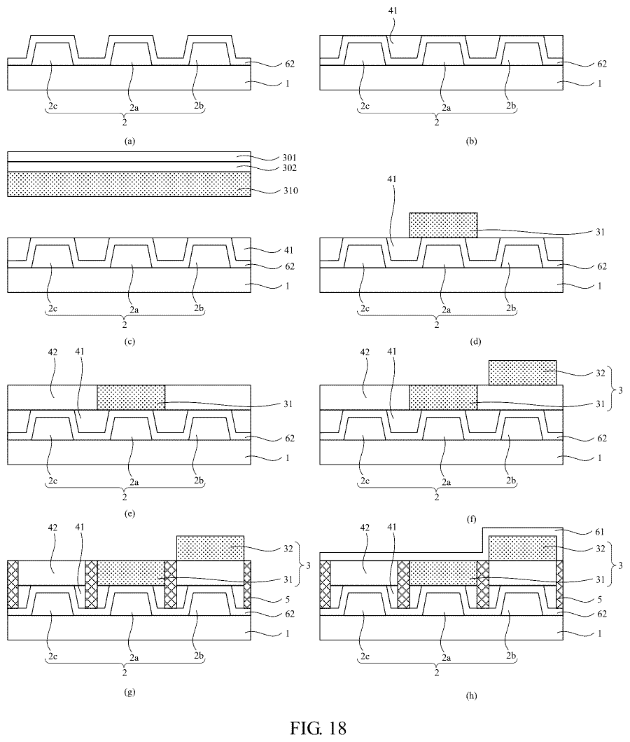

FIG. 18 is a flow chart of another method for manufacturing a light-emitting device according to an embodiment of the present disclosure, which can be used to manufacture the light-emitting device shown in FIG. 1. The method includes the following processes.

In a first process, as shown in part (a) of FIG. 18, a silicon-based driving backplane 1 is provided, a plurality of light-emitting units 2 are formed on the silicon-based driving backplane 1, and the plurality of light-emitting units 2 are disposed in an array on a side of the silicon-based driving backplane 1. A second transflective layer 62 is formed on the side, away from the silicon-based driving backplane 1, of the plurality of light-emitting units 2 by, for example deposition. Optionally, the plurality of light-emitting units 2 are formed on the silicon-based driving backplane 1 by, for example metal-to-metal bonding or a die bond mounting, where the die bond mounting includes a process of printing a solder paste or a flux and a process of pick-and-place.

In a second process, as shown in part (b) of FIG. 18, the first adhesion layer 41 is formed on the surface of the second transflective layer 62 by, for example spin-coating.

In a third process, as shown in part (c) of FIG. 18, a sapphire base 301 having a buffer layer 302 on the surface of the sapphire base 301 is provided, and an entire layer of the first multi-quantum wells 310 is acquired by forming alternatively stacked layers of barrier layers and well layers by, for example, deposition, on the buffer layer 302. The entire layer of the first multi-quantum wells 310 is affixed to the surface of the first adhesion layer 41. Optionally, the thickness of the buffer layer 302 is about 3 μm. Optionally, adhering the entire layer of the first multi-quantum wells 310 to the surface of the first adhesion layer 41 includes: achieving a bonding connection between the first multi-quantum wells 310 and the plurality of light-emitting units 2 under a bonding pressure ranging from 4000N to 15000N and a temperature of less than 300° C. A bonding force between the first multi-quantum wells 310 and the plurality of light-emitting units 2 is greater than 0.05N after the bonding being completed.

In a fourth process, as shown in part (d) of FIG. 18, the sapphire base 301 is removed by, for example, laser lift off (LLO), and the buffer layer 302 is thinned and removed by, for example, plasma etching; and the first color conversion layer 31 is acquired by performing a pattering process on the first multi-quantum wells 310, and the first color conversion layer 31 is disposed above the first light-emitting unit 2a. Optionally, performing a pattering process on the first multi-quantum wells 310 includes performing the plasma etching using a gas mixture of chlorine and iodine chloride. Optionally, the rate of plasma etching is controlled by modulating the power.

In a fifth process, as shown in part (e) of FIG. 18, a second adhesion layer 42 is formed on the surface, away from the silicon-based driving backplane 1, of the first color conversion layer 31 by, for example, coating.

In a sixth process, as shown in part (f) of FIG. 18, a whole layer of the second multi-quantum wells is adhered to the surface of the second adhesion layer 42 in a manner similar to the third process. The second color conversion layer 32 is acquired by performing a patterning process on the second multi-quantum wells, and the second color conversion layer 32 is disposed above the second light-emitting unit 2b.

In a seventh process, as shown in part (g) of FIG. 18, a plurality of recesses are prepared in the first adhesion layer 41 and the second adhesion layer 42 by processes such as photoresist coating, exposure, developing, etching, stripping, and the like, and the plurality of recesses are disposed between the first color conversion layer 31 and the second color conversion layer 32, as well as between two adjacent light-emitting units 2. The retaining walls 5 are formed in the plurality of recesses by processes such as photoresist coating, exposure, developing, deposition, stripping, and the like in these vias.

In an eighth process, as shown in part (h) of FIG. 18, a first transflective layer 61 is formed by, for example, deposition on the side, away from the silicon-based driving backplane 1, of the retaining wall 5 and the second color conversion layer 32. The light-emitting device shown in FIG. 1 is acquired.

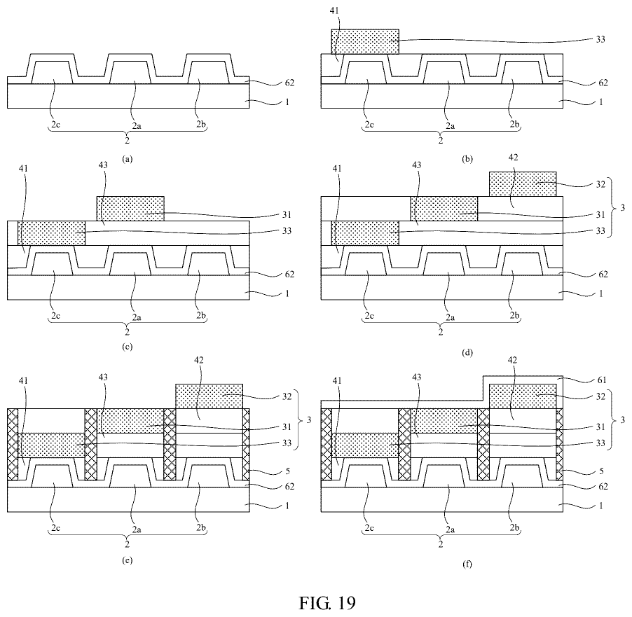

FIG. 19 is a flow chart of another method for manufacturing a light-emitting device according to an embodiment of the present disclosure. The method can be used to manufacture the light-emitting device shown in FIG. 7. The method includes the following processes.

In a first process, as shown in part (a) of FIG. 19, a silicon-based driving backplane 1 is provided, a plurality of light-emitting units 2 are formed on the silicon-based driving backplane 1, and the plurality of light-emitting units 2 is disposed in an array on a side of the silicon-based driving backplane 1. A second transflective layer 62 is formed on a side, away from the silicon-based driving backplane 1, of the plurality of light-emitting units 2 by, for example, deposition.

In a second process, as shown in part (b) of FIG. 19, a first adhesion layer 41 is formed on a surface of the second transflective layer 62 by, for example, spin-coating. A whole layer of the third multi-quantum wells is adhered to the surface of the first adhesion layer 41 in a manner similar to the manner shown in part (c) of FIG. 18. A third color conversion layer 33 is acquired by performing a patterning process on the third multi-quantum wells, and the third color conversion layer 33 is disposed above the third light-emitting unit 2c.

In a third process, as shown in part (c) of FIG. 19, a third adhesion layer 43 is formed on the surface, away from the silicon-based driving backplane 1, of the third color conversion layer 33 by, for example, coating. A whole layer of the first multi-quantum wells is affixed to the surface of the third adhesion layer 43 in a manner similar to the manner shown in part (c) of FIG. 18. A first color conversion layer 31 is acquired by performing a patterning process on the first multi-quantum wells, and the first color conversion layer 31 is disposed above the first light-emitting unit 2a.

In a fourth process, as shown in part (d) of FIG. 19, a second adhesion layer 42 is formed by, for example, coating on a surface, away from the silicon-based driving backplane 1, of the first color conversion layer 31. A whole layer of the second multi-quantum wells is adhered to the surface of the second adhesion layer 42 in a manner similar to the manner shown in part (c) of FIG. 18. The second color conversion layer 32 is acquired by performing a patterning process on the second multi-quantum wells, and the second color conversion layer 32 is disposed above the second light-emitting unit 2b.

In a fifth process, as shown in part (e) of FIG. 19, a plurality of recesses are provided in the first adhesion layer 41, the second adhesion layer 42, and the third adhesion layer 43 by processes such as photoresist coating, exposure, developing, etching, stripping, and the like, and the plurality of recesses extend to spaces between the first color conversion layer 31, the second color conversion layer 32, and the third color conversion layer 33 that are adjacent, and extend between two adjacent light-emitting units 2. The retaining walls 5 are formed in the plurality of recesses by processes such as photoresist coating, exposure, developing, deposition, stripping, and the like in these recesses.

In a sixth process, as shown in part (f) of FIG. 19, a first transflective layer 61 is formed by, for example, deposition on the side, away from the silicon-based driving backplane 1, of the retaining wall 5 and the second color conversion layer 32. Thus, the light-emitting device shown in FIG. 7 is acquired.

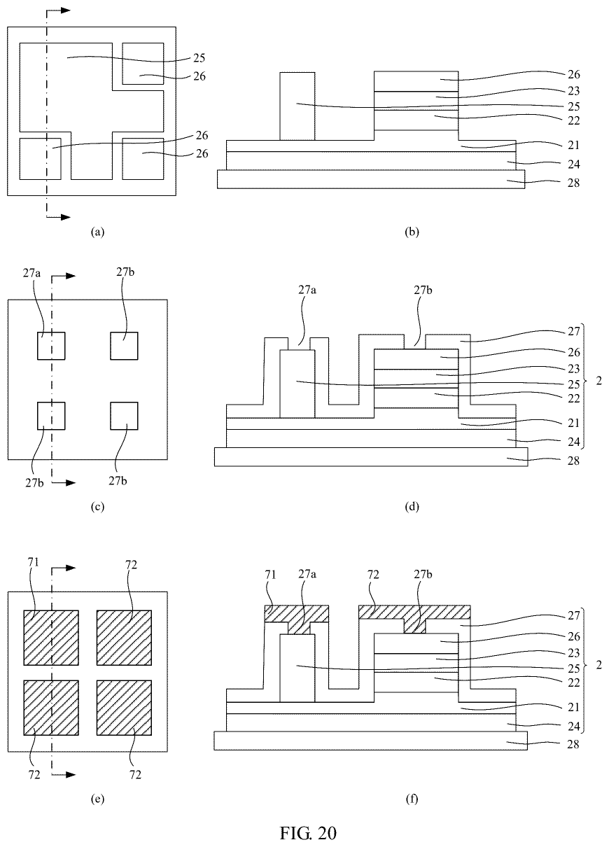

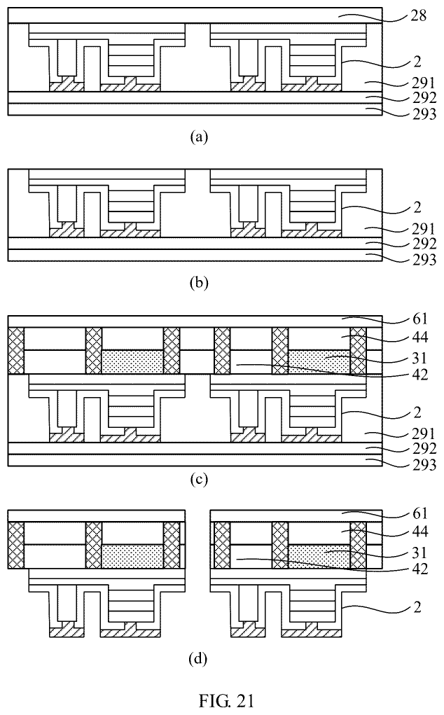

FIG. 20 is a first part of a flow chart of another method for manufacturing a light-emitting unit according to an embodiment of the present disclosure, and the light-emitting unit acquired by the method shown in FIG. 20 is the light-emitting unit in the embodiment shown in FIGS. 8 to 11. In FIG. 20, part (b) is a schematic cross-sectional structural diagram along the shown section line in part (a), part (d) is a schematic cross-sectional structural diagram along the shown section line in part (c), and part (f) is a schematic cross-sectional structural diagram along the shown section line in part (e). FIG. 21 is a second part of the flow chart of another method for manufacturing a light-emitting unit according to an embodiment of the present disclosure. The method includes the following processes.

In a first process, as shown in parts (a) and (b) of FIG. 20, the whole layers of buffer layer 24, a first doped layer 21, a multi-quantum well layer 22, a second doped layer 23, and a conductive layer 26 are sequentially formed by, for example, deposition on a base 28 (e.g., a sapphire base). The conductive layer 26 is formed by performing a patterning process on the multi-quantum well layer 22, the second doped layer 23, and the conductive layer 26, and by etching part of the first doped layer 21. The plurality of light-emitting units are divided into a plurality of groups by deeply etching the buffer layer 24 and the first doped layer 21, and each of the plurality of groups includes a plurality of light-emitting units 2 that form an integrative structure. A layer of raised electrode material is formed on the surface of the conductive layer 26 by means of, for example, deposition, the raised electrode 25 is acquired by performing a patterning process on the raised electrode material, and the raised electrode 25 is subjected to a high temperature annealing process to achieve good ohmic contact. Optionally, the patterning process for the conductive layer 26 includes wet or dry etching for the conductive layer 26. Optionally, the first doped layer 21 is partially etched by plasma etching such as the gas plasma etching, wherein the gas for plasma etching is a gas mixture of chlorine and iodine chloride. Optionally, partially etching the first doped layer 21 means etching away, in a partial region, the first doped layer 21 with a thickness of 0.8 μm to 0.9 μm, to ensure that the multi-quantum well layer 22 is completely etched in the partial region.

In a second process, as shown in parts (c) and (d) of FIG. 20, the insulating layer 27 is formed by means of, for example, PECVD (plasma enhanced chemical vapor deposition). By means of processes such as photoresist coating, exposing, developing, etching, stripping, and the like, the insulating layer 27 is provided with a plurality of first via holes 27a exposing the raised electrode 25 and a plurality of second via holes 27b exposing the conductive layer 26.

In a third process, as shown in part (e) and part (f) of FIG. 20, a first pin 201 is formed in the first via hole 27a by, for example, deposition, and a second pin 202 is formed in the second via hole 27b by, for example, deposition. A plurality of light-emitting units 2 of an integrative structure in the light-emitting device as shown in FIGS. 8 to 11 are acquired by a plasma etching method and the etching reaches the base 28. Optionally, the etching depth is about 4 μm to 5 μm in this process.

In a fourth process, as shown in part (a) of FIG. 21, an adhesion structure 291 is formed on the side, away from the base 28, of the plurality of light-emitting units 2 by, for example, coating. a deadhesion layer 292 and a temporary carrier 293 (e.g., sapphire or glass) are attached to the adhesion structure 291 by, for example, affixing.

In a fifth process, the base 28 is removed by, for example, laser lift off, as shown in part (b) of FIG. 21.

In a sixth process, as shown in part (c) of FIG. 21, the color conversion layer and the first transflective layer 61 are formed using, for example, the approach shown in FIG. 19 or 20.

In a seventh process, as shown in part (d) of FIG. 21, the temporary carrier 293 is removed by means of, for example, laser lift off. The deadhesion layer 292 and the adhesion structure 291 are removed by means of, for example, ashing. A plurality of separate color conversion layers and a plurality of light-emitting units connected to each of the color conversion layers are acquired by means of, for example, laser cutting. Optionally, one acquired color conversion layer and a plurality of light-emitting units connected to the color conversion layer are connected to a silicon-based driving backplane to acquire a light-emitting device as shown in FIGS. 8 to 11.

Illustratively, the light-emitting unit as shown in FIG. 15 is manufactured by the following processes. Similar to the flow of the manufacturing method shown in FIG. 18 or FIG. 19, for example, in part (d) of FIG. 18, after acquiring the whole layer of the first quantum wells 310, a plurality of recesses are provided in the first quantum wells 31 and the first adhesion layer 41 by processes such as photoresist coating, exposure, developing, etching, stripping, etc., the plurality of recesses being between adjacent first color conversion layers 31 and extending between two adjacent light-emitting units 2. The method of subsequently preparing the first transflective layer 61 is the same as the preparing method shown in FIG. 18 or FIG. 19. Then the light-emitting device as shown in FIG. 15 is acquired. Optionally, the first quantum wells 310 is replaced here with second quantum wells or third quantum wells, correspondingly, a light-emitting device including the second color conversion layer or the third color conversion layer is acquired.

Illustratively, the light-emitting device as shown in FIG. 15 is manufactured by the following processes. Similar to the flows of the manufacturing method shown in FIGS. 20 and 21, in the case that the manufactured light-emitting unit 2 has only one conductive layer 26, correspondingly, one light-emitting unit 2 is connected to only one first pin 201 and one second pin 202, and a plurality of light-emitting units 2 do not share one first pin 201; in part (c) of FIG. 21, only one of the first color conversion layer, the second color conversion layer, or the third color conversion layer is formed, and the formed color conversion layer covers all of the light-emitting units 2; and in part (d) of FIG. 21, in the case that the plurality of separate color conversion layers and the plurality of light-emitting units 2 connected to each of the plurality of color conversion layers are acquired by means of, for example, etching, the plurality of light-emitting units 2 connected to one of the color conversion layers do not form an integrative structure. Optionally, one acquired color conversion layer and the plurality of light-emitting units connected to the color conversion layer are connected to a silicon-based driving backplane to acquire a light-emitting device as shown in FIG. 15.

Illustratively, the light-emitting device as shown in FIG. 16 is manufactured by the following processes. Similar to the flows of the manufacturing method shown in FIGS. 20 and 21, the formed light-emitting unit 2 has only one conductive layer 26, correspondingly, one light-emitting unit 2 is connected to only one first pin 201 and one second pin 202; only one of a first color conversion layer, a second color conversion layer, or a third color conversion layer is formed and the formed color conversion layer covers all of the light-emitting units 2; and a plurality of separate color conversion layers and one light-emitting unit connected to each of the plurality of color conversion layers are acquired by, for example, etching.

Optionally, the patterning process includes processes such as photoresist coating, exposure, developing, etching, stripping, and the like.

Embodiments of the present disclosure further provide a display panel including a base substrate and a plurality of light-emitting devices arranged in an array on a side of the base substrate, the light-emitting device being any of the light-emitting devices described above.

Illustratively, the light-emitting device provided by the embodiments of the present disclosure is a lighting device, such as a backlight, a table lamp, an overhead lamp, a wall lamp, a flashlight, or any other product or component having a lighting function.

Embodiments of the present disclosure further provide a display device including any of the foregoing light-emitting devices and a power supply circuit, the power supply circuit being configured to supply power to the light-emitting devices. Alternatively, the display device includes the foregoing display panel and the power supply circuit, the power supply circuit being configured to supply power to the display panel.

Illustratively, the display device according to an embodiment of the present disclosure is a cell phone, a tablet computer, a television, a monitor, a laptop computer, a digital photo frame, a navigator, or any other product or component having a display function.

The display device achieves the same effect as the foregoing display panel and is not described herein.

The foregoing are only optional embodiments of this application and are not intended to limit this application, and any modifications, equivalent substitutions, improvements, etc., made within the concepts and principles of the application shall be included in the scope of protection of this application.

1. A light-emitting device, comprising a light-emitting layer and a color conversion layer, wherein the light-emitting layer comprises at least one light-emitting unit, and the color conversion layer is disposed on a first surface of the light-emitting layer and the color conversion layer comprises multi-quantum wells and is made of inorganic material.

2. The light-emitting device according to claim 1, wherein the at least one light-emitting unit comprises a first light-emitting unit, a second light-emitting unit and a third light-emitting unit, and the color conversion layer comprises a first color conversion layer and a second color conversion layer stacked sequentially in a direction from close to the light-emitting layer to away from the light-emitting layer;
an orthographic projection of the first color conversion layer on the first surface is at least partially overlapped with an orthographic projection of the first light-emitting unit on the first surface, and the first color conversion layer is configured to convert light emitted by the first light-emitting unit to light of a first color; and
an orthographic projection of the second color conversion layer on the first surface is at least partially overlapped with an orthographic projection of the second light-emitting unit on the first surface, and the second color conversion layer is configured to convert light emitted by the second light-emitting unit to light of a second color.

3. The light-emitting device according to claim 2, wherein the light-emitting device further comprises a first adhesion layer and a second adhesion layer, the first adhesion layer is disposed between the light-emitting layer and the color conversion layer, the second adhesion layer is disposed between the first color conversion layer and the second color conversion layer, and the first adhesion layer and the second adhesion layer are both made of transparent material.

4. The light-emitting device according to claim 3, wherein each of the at least one light-emitting unit is configured for emitting blue light.

5. The light-emitting device according to claim 3, wherein the color conversion layer further comprises a third color conversion layer, and the third color conversion layer is disposed on a side, away from the second color conversion layer, of the first color conversion layer; and
the third color conversion layer is configured to convert light emitted by the third light-emitting unit to light of a third color, and an orthographic projection of the third color conversion layer on the first surface is at least partially overlapped with an orthographic projection of the third light-emitting unit on the first surface.

6. The light-emitting device according to claim 5, wherein each of the at least one light-emitting unit is configured to emit ultraviolet light.

7. The light-emitting device according to claim 2, wherein each of the at least one light-emitting unit comprises a first pin and a second pin, and the first pin and the second pin are disposed on a side, away from the color conversion layer, of the light-emitting unit.

8. The light-emitting device according to claim 7, wherein a first light-emitting unit, a second light-emitting unit and a third light-emitting unit, which are adjacent, form an integrative structure and share one first pin.

9. The light-emitting device according to claim 2, wherein the first color conversion layer comprises laminated M first repeating units, and each of the M first repeating units comprises a first barrier layer and a first well layer stacked in a direction from close to the first surface to away from the first surface; and
the second color conversion layer comprises laminated N second repeating units, and each of the N second repeating units comprises a second barrier layer and a second well layer stacked in the direction from close to the first surface to away from the first surface;
wherein M and N are positive integers, 20<M≤70 and 20<N≤70.

10. The light-emitting device according to claim 9, wherein the first barrier layer is made of InGaN and the first well layer is made of GaN, or the first barrier layer is made of CaSSe and the first well layer is made of CaSe, or the first barrier layer is made of CdMgZnSe and the first well layer is made of CdZnSe; and
the second barrier layer is made of InGaN and the second well layer is made of GaN, or the second barrier layer is made of CaSSe and the second well layer is made of CaSe, or the second barrier layer is made of CdMgZnSe and the second well layer is made of CdZnSe.

11. The light-emitting device according to claim 10, wherein the first barrier layer and the second barrier layer contain indium, and a concentration of indium in the first barrier layer is different from a concentration of indium in the second barrier layer.

12. The light-emitting device according to claim 10, wherein the first barrier layer has a thickness ranging from 10 nm to 30 nm, and the first well layer has a thickness ranging from 2 nm to 5 nm; and the second barrier layer has a thickness ranging from 10 nm to 30 nm, and the second well layer has a thickness ranging from 2 nm to 5 nm.

13. The light-emitting device according to claim 1, wherein each of the at least one light-emitting unit comprises a first doped layer, a multi-quantum well layer, and a second doped layer that are stacked sequentially in a direction from close to the color conversion layer to away from the color conversion layer.

14. The light-emitting device according to claim 13, further comprising a first transflective layer, wherein the first transflective layer is disposed on a side, away from the light-emitting layer, of the color conversion layer, and the first transflective layer is configured for transmitting light that is converted by the color conversion layer after being emitted by the at least one light-emitting unit, and reflecting light emitted by the at least one light-emitting unit.

15. The light-emitting device according to claim 13, further comprising a second transflective layer, wherein the second transflective layer is disposed between the light-emitting layer and the color conversion layer, the second transflective layer covers a sidewall of each of the at least one light-emitting unit, and the second transflective layer is configured for reflecting light that is converted by the color conversion layer after being emitted by the at least one light-emitting unit, and transmitting light emitted by the at least one light-emitting unit.

16. The light-emitting device according to claim 1, further comprising a silicon-based driving backplane, wherein the silicon-based driving backplane is disposed on a side, away from the color conversion layer, of the light-emitting layer and connected to the light-emitting layer.

17. A method for manufacturing a light-emitting device, comprising:
providing a light-emitting layer;
forming a color conversion layer on a first surface of the light-emitting layer;
wherein the light-emitting layer comprises at least one light-emitting unit, the color conversion layer is disposed on the first surface of the light-emitting layer, and the color conversion layer comprises multi-quantum wells and is made of inorganic material.

18. A display panel, comprising a base substrate and a plurality of light-emitting devices arranged in an array on a side of the base substrate, and each of the plurality of light-emitting devices is the light-emitting device as defined in claim 1.

19. A display device, wherein the display device comprises the light-emitting device as defined in claim 1 and a power supply circuit, and the power supply circuit is configured to supply power to the light-emitting device.

20. A display device, wherein the display device comprises the display panel as defined in claim 18 and the power supply circuit, and the power supply circuit is configured to supply power to the display panel.
